(19) United States
(12) Patent Application Publication
(10) Pub. No.: US 2006/0005767 A1
(43) Pub. Date: Jan. 12, 2006

(54) Chamber component having knurled surface

(75) Inventors: Kenneth Tsai, Emerald Hills, CA (US); Abhijit Desai, Fremont, CA (US)

Correspondence Address: APPLIED MATERIALS, INC.;Patent Department, M/S 2061, P.O. Box 450A, Santa Clara, CA, 95052, US

(73) Assignee: Applied Materials, Inc.

(21) Appl. No.: 10/880,235

(22) Filed: Jun. 28, 2004

(51) Int. Cl. C23C 16/00

(52) U.S. Cl. 118/715

(57) ABSTRACT

A substrate retaining clamp for a substrate processing chamber has a ring having an annular portion that surrounds a substrate in the chamber. The ring also has an overhang ledge to cover a periphery of the substrate. The retaining clamp has a knurled exposed surface of the overhang ledge that has spaced apart knurled ridges and furrows. In one version, the knurled ridges and furrows are concentric and radially spaced apart. The knurled exposed surface having the knurled ridges and furrows provides improved performance in the processing of substrates, and especially in high temperature processes.

### BACKGROUND

The present invention relates to components for a substrate processing chamber.

In the processing of substrates, such as semiconductor wafers and displays, a substrate is placed in a process chamber and exposed to an energized gas to deposit or etch material on the substrate. A typical process chamber comprises process components including an enclosure wall that encloses a process zone, a gas supply to provide a gas in the chamber, a gas energizer to energize the process gas to process the substrate, a substrate support, and a gas exhaust. The process chamber components can also comprise a process kit, which typically includes one or more parts that can assist in securing and protecting the substrate during processing. An example of a process kit component is a retaining clamp, which can at least partially encircle a periphery of a substrate to secure the substrate on the support. The retaining clamp can also at least partially cover one or more of the substrate and support to reduce the deposition of process residues thereon.

During processing of a substrate in a process chamber, process residues are generated that can deposit on internal surfaces in the chamber. For example, process residues can deposit on surfaces including a surface of the retaining clamp, a substrate support surface, and surfaces of enclosure walls. In subsequent process cycles, the deposited process residues can “flake off” of the internal chamber surfaces to fall upon and contaminate the substrate. To solve this problem, the surfaces of components in the chamber are often textured to reduce the contamination of the substrates by process residues. Process residues adhere to these textured surfaces, and the incidence of contamination of the substrates by the process residues is reduced.

In one version, a textured component surface can be formed by directing an electromagnetic energy beam onto a component surface to form depressions and protrusions to which process deposits adhere. In yet another version, a textured surface can be provided by forming a textured coating on a component. However, such surfaces may not sufficiently reduce the problems associated with the build-up of process residue. In particular, the accumulation of process residues about the substrate receiving area of the substrate support can be problematic, and may not be sufficiently reduced by such textured surfaces. For example, process residues can accumulate on surfaces about the retaining clamp and on the substrate receiving surface. As the dimensions of the substrate receiving area are typically carefully selected to provide a close fit to the substrate, the build-up of process residues about the receiving area can result in an improper fit of the substrate on the support, and even “sticking” of substrate to one or more of the receiving surface and clamp ring. This “sticking” of the substrate can be especially problematic, for example, in high temperature processes such as aluminum re-flow processes, in which aluminum-containing material and other process residues can migrate about various surfaces in the chamber.

Accordingly, it is desirable to have a chamber component and method that is capable of reducing the accumulation of process residues about a substrate receiving area. It is further desirable to have a component and method that is capable of reducing the “sticking” of substrates to portions of a substrate support.

### SUMMARY

In one version, a substrate retaining clamp for a substrate processing chamber has a ring having an annular portion that surrounds a substrate in the chamber. The ring also has an overhang ledge to cover a periphery of the substrate. The retaining clamp has a knurled exposed surface on the overhang ledge that has spaced apart knurled ridges and furrows. In one version, the knurled exposed surface has concentric and radially spaced apart knurled ridges and furrows, with the knurled ridges and furrows having an amplitude from a centerline that is at least about 0.5 millimeters and less than about 2.5 millimeters, and having a peak to peak distance between adjacent knurled ridges of at least about 0.5 millimeters and less than about 2.5 millimeters. The retaining clamp can have the knurled exposed surface on a top surface that extends across the overhang ledge and even across at least a portion of the annular portion, and on an exterior side surface of the annular portion. The knurled exposed surface having the knurled ridges and furrows provides improved performance in the processing of substrates, and especially in high temperature processes.

In one version of a method of fabricating a substrate retaining clamp for a process chamber, a ring is formed having an annular portion having a diameter sufficiently large to surround a substrate in the chamber, and an overhang ledge adapted to seat on a periphery of the substrate. An exposed surface of the overhang ledge is knurled to form spaced apart knurled ridges and furrows.

### DRAWINGS

These features, aspects, and advantages of the present invention will become better understood with regard to the following description, appended claims, and accompanying drawings, which illustrate examples of the invention. However, it is to be understood that each of the features can be used in the invention in general, not merely in the context of the particular drawings, and the invention includes any combination of these features, where:

FIG. 1a is a top view of an embodiment of a retaining clamp having a knurled surface;

FIG. 1b is a sectional side view of an embodiment of a retaining clamp having a knurled surface;

FIG. 2a is a plan view of an embodiment of a knurling tool having hardened edges;

FIG. 2b is a sectional side view of an embodiment of the hardened edges of the knurling tool of FIG. 2b; and

FIG. 3 is a sectional side view of an embodiment of a sputtering chamber having a retaining clamp with the knurled surface.

### DESCRIPTION

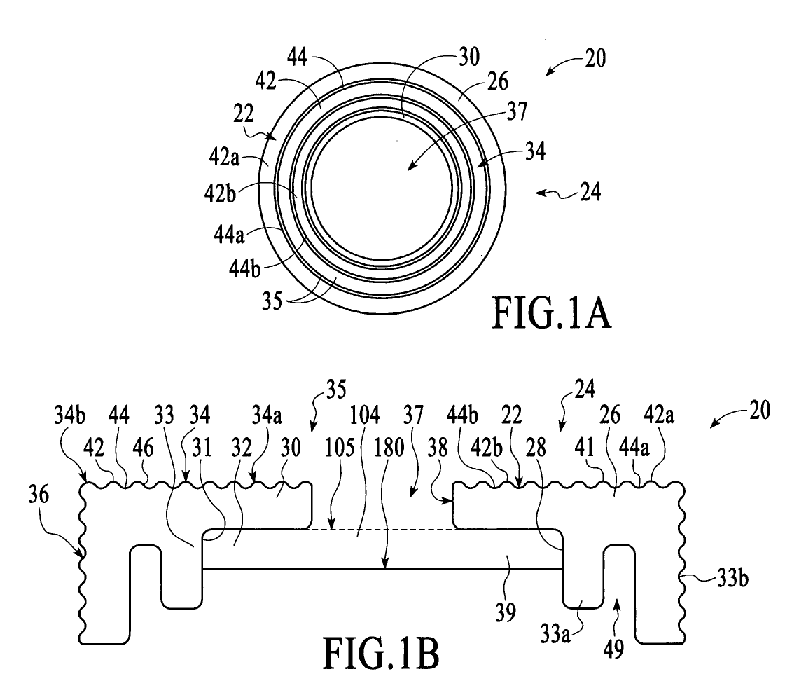

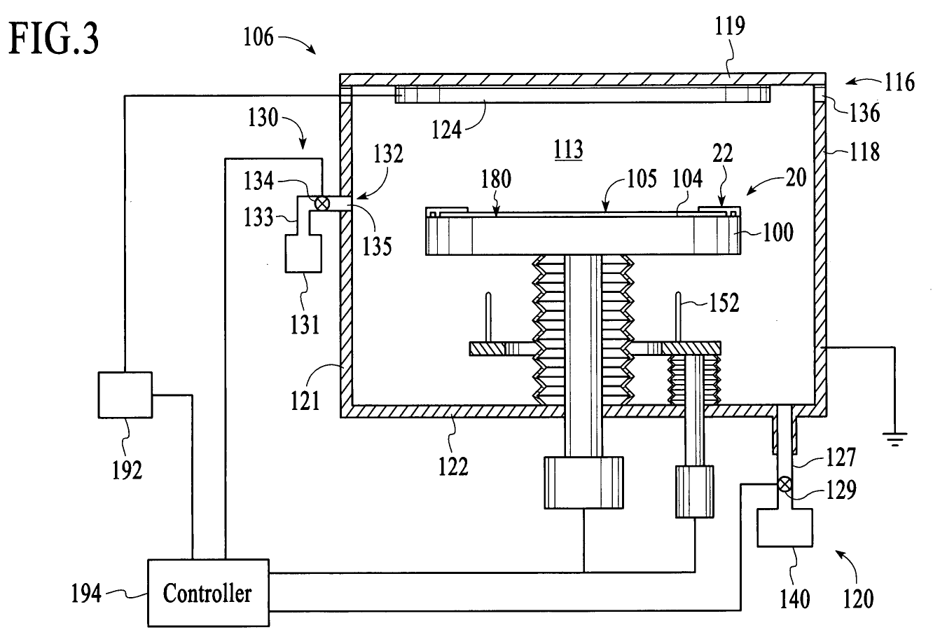

A substrate processing chamber 106 (shown in FIG. 3) comprises a substrate retaining clamp 20 having a surface 22 that is textured to reduce the contamination of substrates 104 by process residues, as shown for example in FIGS. 1a and 1b. The substrate retaining clamp 20 is capable of securing a substrate 104 onto a substrate receiving surface 180 of a substrate support 100, and may also be capable of reducing the deposition of process residues onto the substrate 104.

In the version shown in FIGS. 1a and 1b, the substrate retaining clamp 20 comprises a ring 24 that has an annular outer portion 26 about the substrate 104, and an overhang ledge 30 that extends at least partially over a periphery of the substrate 104. A top surface 105 of the substrate 104 is exposed through a substantially circular opening 37 in the ring 24. The annular outer portion 26 of the ring 24 comprises an inner wall 33 having a diameter 31 that is sufficiently large to at least partially surround a perimeter 28 of a substrate 104 positioned on the support 100, thereby at least partially securing the substrate 104 on the support 100. The overhang ledge 30 extends inwardly from the annular outer portion 26 to at least partially cover a periphery 39 of the substrate 104, and can extend from about 1 millimeter to about 1.5 millimeters over the periphery 39 of the substrate 104 and even seat on the periphery 39 of the substrate 104. In the version shown in FIGS. 1a and 1b, a top surface 34 of the retaining clamp 20 faces a process zone 113 in the chamber 106 and extends across both the overhang ledge 30 and annular portion 26 of the retaining clamp 20. The top surface 34 may be substantially parallel to a top surface 105 of the substrate 104. The overhang ledge 30 can protect the peripheral portion of the substrate 104 from the re-deposition of process residues onto the substrate 104, and can also hold or “clamp” the substrate 104 to secure the substrate 104 to a substrate receiving surface 180 of the support 100 during processing.

The retaining clamp 20 can comprise further structural elements to connect the retaining clamp 20 to a portion of the process chamber 106. For example, as shown in FIG. 1b, the retaining clamp 20 can comprise one or more downwardly extending walls 33a,b. A first downwardly extending wall 33a can comprise a first annular wall having an inner diameter 31 that surrounds and is adjacent to the outer perimeter 28 of the substrate 104, to protect the sides of the substrate 104. The overhang ledge 30 may extend radially inwardly from the first downwardly extending wall 33a. A second downwardly extending wall 33b can comprise a second annular wall that is concentrically exterior to the first downwardly extending wall 33a, with a connecting space 49 remaining between the first and second walls 33a,b. The connecting space 49 may be capable of accommodating a portion of the support 100 to connect the retaining clamp 20 to the support 100, as shown for example in FIG. 3. The second downwardly extending wall 33b can also extend downwardly a sufficient distance to at least partially cover and inhibit erosion of interior parts of the substrate support 100.

It has been discovered that improved processing results are provided by forming a knurled exposed surface 22 on the at least a portion of the retaining clamp. The knurled exposed surface 22 can be formed by pressing one or more hardened edges 54 into a surface of the retaining clamp 20, for example by rolling the hardened edges over the surface, thereby imprinting or embossing a pattern of features 35 onto the surface. The pattern of features 35 can comprise depressions and projections on the knurled exposed surface 22. In the examples shown in FIGS. 1a and 1b, the features 35 comprise a plurality of projections and depressions in the knurled exposed surface 22 that comprise raised ridges 42 as well as depressed furrows 44 or channels. The raised ridges 42 and depressed furrows 44 comprise amplitudes about a centerline 46 representing a median height of the knurled exposed surface 22 that improves the adhesion of residues to the knurled exposed surface 22. The amplitudes of the ridges 42 and furrows 44 comprise the maximum departure of the ridge height or furrow depth from the centerline or average surface height. In one version, one or more of the ridges 42 comprise an amplitude above the centerline 46 that is at least about 0.5 millimeters and less than about 2.5 millimeters, such as from about 1 millimeter to about 1.5 millimeters. The furrows 44 comprise channels or trenches in the knurled exposed surface 22 that extend below the centerline 46 to provide depressions in the knurled exposed surface 22. For example, one or more of the furrows can comprise an amplitude below the centerline 46 of at least about 0.5 millimeters and less than about 2.5 millimeters, such as from about 1 millimeter to about 1.5 millimeters.

The number of knurled ridges 42 and furrows 44 provided by the pattern of features 35 is also selected to provide optimized adhesion of the residues. For example, the retaining clamp 20 can comprise from about 100 to about 150 ridges 42 and about 100 to about 150 furrows 44. The knurled exposed surface 22 having the ridges 42 and furrows 44 provides improved substrate processing performance by providing features 35 capable of collecting process residues to reduce substrate contamination and “sticking” of the substrate 104 to the support 100.

The knurled exposed surface 22 can be provided on portions of the retaining clamp 20 that improve the adhesion of process residues, such as on surfaces that are exposed to energized gases in the chamber 106. In one version, the knurled exposed surface 22 comprises at least a portion of an exposed surface of the overhang ledge 30. Providing the knurled exposed surface 22 on the overhang ledge 30 reduces the amount of residue that can collect in the substrate receiving area to reduce contamination and sticking of the substrate 104. For example, the knurled exposed surface 22 can comprise at least a portion of and even substantially an entire top surface 34a of the overhang ledge 30 to reduce the flow of residues towards the substrate 104. The knurled exposed surface can also or alternatively comprise at least a portion of a top surface 34b of the outer annular portion 26. In one version, the knurled exposed surface 22 extends across substantially the entire top surface 34 of the retaining clamp 20, as shown for example in FIGS. 1a and 1b.

The knurled exposed surface 22 can also comprise at least a portion of another surface of the retaining clamp 20, such as at least a portion of an exterior side surface 36 of the clamp 20. The exterior side surface 36 extends downwardly over the second outer sidewall 33b, and may be substantially perpendicular to the top surface 34 of the retaining clamp 20. In one version, the retaining clamp 20 comprises a substantially continuously knurled exposed surface 22 that extends across the top surface 34 and down at least a portion of the outer side surface 36, as shown for example in FIG. 1b. Other portions of the clamp 20 can also comprise the knurled exposed surface 22, such as for example the interior side surface 38 of the overhang ledge 30.

In one version, the knurled exposed surface 22 comprises ridges 42 and furrows 44 that are arranged concentrically with respect to one another. For example, the knurled exposed surface 22 may comprise a radial pattern of ridges 42 and furrows 44 on at least a portion of the top surface 34 that encircle the central opening 37 in the retaining clamp 20, and may even be substantially coaxial with the central opening 37, as shown for example in FIG. 1a. The ridges 42 and furrows 44 encircling the central opening 37 increase in circumference with increasing radius of the retaining clamp 20, such that interior ridges 42a and furrows 44a that are closer to the central opening 37 are nested concentrically inside exterior ridges 42b and furrows 44b that are towards the periphery of the retaining clamp 20. The ridges 42 and furrows 44 are preferably substantially circular and can form rings about the central opening 37 on the surface 22. The ridges 42 and furrows 44 may also comprise other concentric shapes, such as concentric ovals, or other elliptical shapes. The ridges 42 and furrows 44 can also alternate radially along the knurled exposed surface 22, to provide a plurality of features 35 to which process residues can adhere, as shown for example in FIG. 1a.

The retaining clamp 20 comprising the knurled exposed surface 22 having the concentric ridges 42 and furrows 44 provides an advantage over other surfaces, because the knurled exposed surface 22 is especially suited to reduce the flow of process deposits towards the substrate 104. For example, in high temperature processes that can re-circulate and re-flow deposits about the chamber 106, the concentric pattern of ridges 42 and furrows 44 reduces the flow of deposits towards the substrate 104. The concentric furrows 44 act as a trap or a moat to catch process residues being re-circulated towards the substrate 104, and the concentric ridges 42 act as barriers to block the progress of residues flowing towards the substrate 104. The circular symmetry of the ridges 42 and furrows 44 provides optimized inhibition of the progress of these residues by blocking a radial flow path of residues that is directed towards the substrate 104.

The ridges 42 and furrows 44 can be radially spaced apart along the knurled exposed surface 22 to provide a desired distance between the ridges 42 and furrows 44. In one version, the ridges 42 and furrows 44 are periodically spaced apart from one another to provide a regularly spaced pattern of features 35. For example, the ridges 42 can comprise peaks 41 corresponding to the tallest point on each ridge 42, and the ridges and furrows 44 can be periodically spaced apart to provide a peak-to-peak distance between adjacent ridges 42 of at least about 0.5 millimeters and less than about 2.5 millimeters, such as at least about 1 millimeter and less than about 1.5 millimeters, with furrows 44 separating the adjacent ridges 42, as shown in FIGS. 1a and 1b. Alternatively, the distance or period between adjacent ridges 42 can be varied with increasing radius of the retaining clamp 20.

In a method of fabricating the retaining clamp 20 comprising the knurled surface 22, a retaining clamp 20 comprising the desired shape is formed. The desired shape of the retaining clamp 20 can be formed by a shaping method such as for example a computer numeric control method (CNC). In this method, the desired shape is provided by using a computer controlled cutting device that is capable of cutting a metal preform in response to control signals from a computer controller. The computer controller comprises program code to direct the cutting device to cut away portions of the preform to leave the desired clamp shape, such as a retaining clamp 20 having a ring comprising an annular portion 26 having a diameter 31 sufficiently large to surround a substrate 104, and an overhang ledge 30 adapted to seat on the substrate 104. Other methods of fabricating a retaining clamp 20 comprising the desired shape can also be used, such as for example casting, drop-forging, stamping, and other methods that are known to one of ordinary skill in the art. Metals suitable for fabricating the retaining clamp 20 can comprise, for example, at least one of stainless steel, aluminum, titanium, and copper. In one version, the retaining clamp is composed of stainless steel.

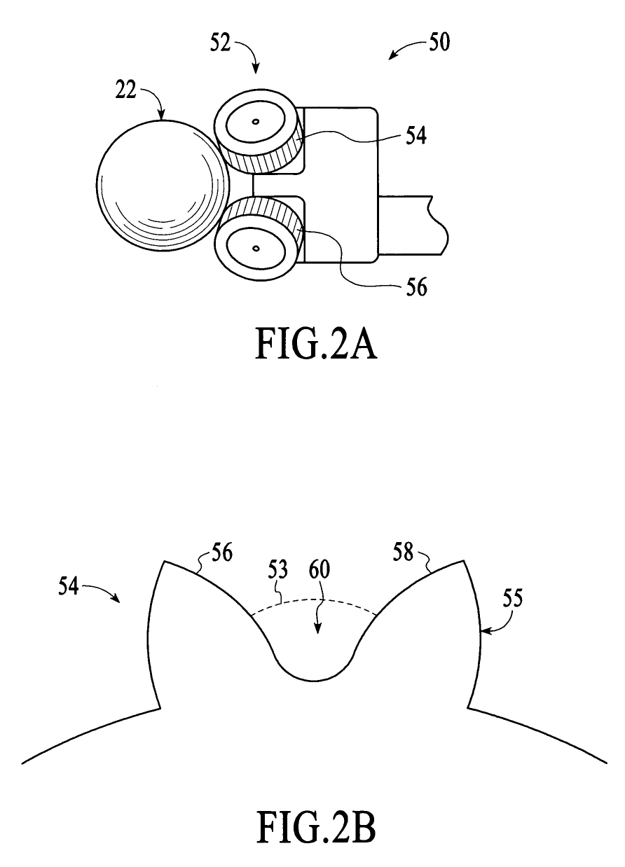

Once the retaining clamp 20 having the desired bulk shape has been formed, the knurling process is performed to form the knurled exposed surface 22 on at least a portion of the clamp 20, such as on the overhang ledge 30. A knurling tool 50 comprising hardened edges 56 is provided to form the knurled features 35 on the clamp 20, as shown for example in FIGS. 2a and 2b. The hardened edges 56 of the knurling tool 50 are formed of a hard material and comprise a shape that is capable of indenting the surface of the retaining clamp 20. In one version, the knurling tool 50 comprises a knurling head 52 having the hardened edges 56 on wheels 54 that can be run across a surface of the retaining clamp 20. The hardened edges 56 comprise a plurality of teeth 58 that press and indent into the surface 22 as they are drawn across the surface 22. The regions where the teeth 58 are pressed into the surface 22 form indentations that correspond to the furrows 44. The ridges 42 in the surface 22 correspond to the gaps 60 between the teeth 58, as shown for example in FIG. 2b. Accordingly, the teeth 58 desirably comprise amplitudes from a centerline 53 representing a median height of a surface 55 of the knurling wheel 54 that is sufficiently large to form furrows 42 and ridges 44 having the desired amplitudes, and also comprise a distance between teeth that is suitable to provide the desired peak-to-peak distance between the ridges 42. A suitable amplitude of the teeth may be from about 0.5 millimeters to about 2.5 millimeters, such as from about 1 millimeter to about 1.5 millimeters, and a suitable peak-to-peak distance may be from about 0.5 millimeters to about 2.5 millimeters, such as from about 1 millimeter to about 1.5 millimeter. In one embodiment of the knurling process, the retaining clamp 20 is secured in a holding device, such as for example a lathe (not shown), while the knurling head 52 is moved across the clamp surface. Alternatively, the surface of the retaining clamp 20 may be moved over the knurling head 52 while the knurling tool 50 is kept still to form the knurled exposed surface 22.

The configuration of the teeth 58 on the knurling head 52 is selected to provide the desired pattern of features 35. For example, in the version shown in FIG. 2a, the knurling head 52 comprises teeth 58 that are perpendicular to a direction of motion of the wheels 54. The knurling head 52 can also comprise teeth 58 that are parallel to the motion of the wheel. The wheels 54 are drawn across the surface 22 of the clamp 20 in a direction such that the teeth 58 are imprinted to form the desired pattern of concentric ridges 42 and furrows 44. For example, a knurling head 52 having a suitable configuration of teeth 58 can be drawn across the surface 22 in a substantially circular path on the surface 22, to provide the concentric ridges 42 and furrows 44. Also, a second pattern of features 35 may be imprinted over the first pattern of features 35 to make a desired surface configuration. For example, a “diamond” patterned knurled surface 22 can be provided by forming a second pattern comprising ridges and furrows that are offset from the first pattern of furrows and ridges. However, a knurled surface 22 having a single pattern consisting essentially of the concentric ridges and furrows may be desirable to provide the optimal blocking of the flow of process deposits towards the substrate 104.

The retaining clamp 20 having the knurled surface 22 can be especially beneficial in high temperature processes such as aluminum re-flow processes that are used to form a layer of aluminum on a substrate 104. An example of an aluminum re-flow process is described in U.S. Pat. No. 6,660,135 to Yu et al, issued on Dec. 9, 2003 and commonly assigned to Applied Materials, which is herein incorporated by reference in its entirety. To form a uniform layer of aluminum on a substrate, one or more initial layers of aluminum can be deposited on a substrate 104 by a physical vapor deposition method in which an energized sputtering gas is provided in a chamber to sputter aluminum material from a target and onto a substrate 104. The substrate 104 having the one or more layers of aluminum is then subjected to a re-flow process to form the more uniform layer of aluminum. In the re-flow process, the substrate 104 having the layer of aluminum is heated to a temperature that is sufficiently high such that the aluminum migrates and re-distributes about the surface 105 of the substrate 104. The re-flowing process typically provides a more uniform layer of aluminum, as the process can fill channels or crevices in the surface 105 of the substrate 104. A typical re-flowing process may involve heating the substrate 104 to a temperature of at least about 250° C., such as from about 250° C. to about 500° C. The improved retaining clamp 20 having the knurled surface 22 inhibits the flow of process residues towards the substrate 104, and also collects loose residue to inhibit deposition of the residues on the substrate 104 or about the substrate receiving area.

The improved retaining clamp 20 having the knurled surface 22 provides improved results over retaining clamps 20 without a knurled surface 22. For example, the improved retaining clamp 20 may allow for at least about 30% more RF watt hours of chamber processing, before cleaning or replacement of the retaining clamp 20 is required. Thus, the improved retaining clamp 20 having the knurled surface 22 allows for the re-flow processing of substantially more substrates 104 than a clamp 20 without the knurled surface 22 before failure of the retaining clamp 20, and thus provides substantially improved process performance over clamps 20 without the knurled surface 22.

After processing a number of substrates 104, the surface 22 of the retaining clamp 20 can be cleaned to remove any process residues, such as aluminum containing residues. In one version, the aluminum-containing residues can be removed by exposing the surface 22 of the clamp 20 to a cleaning solution capable of dissolving or otherwise removing the residues from the surface 22. For example, the surface 22 can be immersed in the cleaning solution, or the cleaning solution can be wiped or sprayed onto the surface 22. The cleaning solution can comprise an acidic solution, such as for example at least one of H₃PO₄, HNO₃ and HF. Other solutions can also be provided alone or in sequence with an acidic solution, such as a basic solution comprising KOH, and optionally solutions comprising H₂O_{2.}

In one version of a cleaning process, a retaining clamp 20 comprising stainless steel is cleaned to remove aluminum-containing residues by immersing the surface 22 of the clamp 20 in an initial basic cleaning solution comprising about 1 kg of KOH in about 6 liters of de-ionized water. In another version, the surface 22 is immersed in an initial acidic cleaning solution comprising 20 parts by volume of H₃PO_{4,} 5 parts by volume of HNO₃, and 1 part by volume of de-ionized water, while heating the solution to a temperature of from about 60° C. to about 70° C. In still another version, the surface 22 is immersed in an initial cleaning solution 1 part by weight of KOH, 10 parts by weight of H₂O₂ and 20 parts by weight of de-ionized water. Any of these initial cleaning solutions can be followed by immersion of the surface 22 in one or more subsequent cleaning solutions, such as an acidic cleaning solution comprising 20% by volume HNO_{3,} 3% by volume HF and the remainder de-ionized water, followed by an acidic solution comprising 50% by volume HNO₃ and 50% by volume of de-ionized water. The cleaning processes are capable of removing aluminum-containing residues substantially without eroding the retaining clamp 20. An example of a cleaning method is described in U.S. patent application Ser. No. 10/304,535, entitled “Method of Cleaning a Coated Process Chamber Component,” to Wang et al, filed on Nov. 25, 2002 and commonly assigned to Applied Materials. Inc, which is herein incorporated by reference in its entirety.

In one version, the retaining clamp 20 comprising the knurled surface 22 is a part of a process chamber 106 that is capable of performing one or more of an aluminum deposition process and aluminum re-flow process, an embodiment of which is shown in FIG. 3. A suitable chamber may comprise a PVD Al chamber, an embodiment of which is also described in U.S. Pat. No. 6,660,135 to Yu et al, issued Dec. 9, 2003, and commonly assigned to Applied Materials, which is herein incorporated by reference in its entirety. The chamber shown in FIG. 3 comprises enclosure walls 118, which may comprise a ceiling 119, sidewalls 121, and a bottom wall 122 that enclose a process zone 113. A sputtering gas can be introduced into the chamber 106 through a gas supply 130 that includes a sputtering gas source 131, and a gas distributor 132. In the version shown in FIG. 3, the gas distributor 132 comprises one or more conduits 133 having one or more gas flow valves 134 and one or more gas outlets 135 around a periphery of the substrate 104. The sputtering gas can comprise, for example, an inert gas such as argon. A substrate support 100 comprises a substrate receiving surface 180 to receive a substrate 104, and the retaining clamp 20 can be provided on the support 100 to hold or clamp the substrate 104 onto the surface 180. An electrode in the support 100 below the substrate 104 may be powered by an electrode power supply to electrostatically hold the substrate on the support 100 during processing. Spent process gas and process byproducts are exhausted from the chamber 106 through an exhaust 120 which may include an exhaust conduit 127 that receives spent process gas from the process zone 113, a throttle valve 129 to control the pressure of process gas in the chamber 106, and one or more exhaust pumps 140.

The chamber 106 further comprises a sputtering target 124 facing a surface 105 of the substrate 104, and having material to be sputtered onto the substrate 104, such as for example aluminum. The target 124 can be electrically isolated from the chamber 106 by an annular insulator ring 136, and is connected to a power supply 192. The sputtering chamber 106 can also have a shield (not shown) to protect a wall 118 of the chamber 106 from sputtered material. A gas energizer 116, which can include one or more of the power supply 192, target 124, chamber walls 118 and support 100, is capable of energizing the sputtering gas to sputter material from the target 124. The power supply 192 applies a bias voltage to the target 124 with respect to another portion of the chamber 106, such as the chamber sidewall 118. The electric field generated in the chamber 106 from the applied voltage energizes the sputtering gas to form a plasma that energetically impinges upon and bombards the target 124 to sputter material off the target 124 and onto the substrate 104. The support 100 may comprise an electrode that operates as part of the gas energizer 116 by energizing and accelerating ionized material sputtered from the target 124 towards the substrate 104.

To process a substrate 104, the process chamber 106 is evacuated and maintained at a predetermined sub-atmospheric pressure. The substrate 104 is then provided on the support 100 by a substrate transport, such as for example a robot arm and lift pin assembly. The substrate 104 may be held on the support 100 by applying a voltage to an electrode in the support 100 via an electrode power supply. The gas supply 130 provides a process gas to the chamber 106 and the gas energizer 116 energizes the sputtering gas to sputter the target 124 and deposit material on the substrate 104. Effluent generated during the chamber process is exhausted from the chamber 106 by the exhaust 120.

The chamber 106 can be controlled by a controller 194 that comprises program code having instruction sets to operate components of the chamber 106 to process substrates 104 in the chamber 106. For example, the controller 194 can comprise a substrate positioning instruction set to operate one or more of the substrate support 100 and robot arm and lift pins 152 to position a substrate 104 in the chamber 106; a gas flow control instruction set to operate the gas supply 130 and flow control valves to set a flow of gas to the chamber 106; a gas pressure control instruction set to operate the exhaust 120 and throttle valve to maintain a pressure in the chamber 106; a gas energizer control instruction set to operate the gas energizer 116 to set a gas energizing power level; a temperature control instruction set to control temperatures in the chamber 106, such as a temperature of the substrate 104; and a process monitoring instruction set to monitor the process in the chamber 106.

Although exemplary embodiments of the present invention are shown and described, those of ordinary skill in the art may devise other embodiments which incorporate the present invention, and which are also within the scope of the present invention. For example, other retaining clamp configurations other than the exemplary ones described herein can also be provided. Also, the retaining clamp may be a part of process chambers other than those described. Furthermore, relative or positional terms shown with respect to the exemplary embodiments are interchangeable. Therefore, the appended claims should not be limited to the descriptions of the preferred versions, materials, or spatial arrangements described herein to illustrate the invention.

What is claimed is:

1. A substrate retaining clamp for a substrate processing chamber, the retaining clamp comprising:
(a) a ring comprising an annular portion that surrounds a substrate in the chamber, and an overhang ledge to cover a periphery of the substrate; and
(b) a knurled exposed surface on the overhang ledge, the knurled exposed surface comprising spaced apart knurled ridges and furrows.

2. A clamp according to claim 1 wherein the knurled exposed surface is a surface of the overhang ledge, and comprises concentric ridges and furrows that are radially spaced apart from one another.

3. A clamp according to claim 1 wherein the ridges and furrows each have an amplitude from a centerline that is at least about 0.5 millimeters and less than about 2.5 millimeters.

4. A clamp according to claim 1 wherein adjacent ridges have a peak to peak distance of at least about 0.5 millimeters and less than about 2.5 millimeters.

5. A clamp according to claim 1 wherein the knurled ridges and furrows are periodically spaced apart from one another.

6. A clamp according to claim 1 wherein the ring comprises at least one of stainless steel, titanium, copper or aluminum.

7. A method of fabricating a substrate retaining clamp for a process chamber, the method comprising:
(a) forming a ring comprising an annular portion having a diameter sufficiently large to surround a substrate in the chamber, and having an overhang ledge adapted to seat on a periphery of the substrate; and
(b) knurling an exposed surface of the overhang ledge to form spaced apart knurled ridges and furrows.

8. A method according to claim 7 wherein (b) comprises running a knurling tool comprising a plurality of hardened knurling edges across the exposed surface.

9. A method according to claim 8 wherein (b) comprises running the knurling tool in a substantially circular path across the exposed surface.

10. A method according to claim 8 wherein (b) comprises running a knurling tool having hardened edges adapted to form concentric and radially spaced apart knurled ridges and furrows on the exposed surface.

11. A method according to claim 8 wherein (b) comprises running a knurling tool having hardened knurling edges comprising teeth across the exposed surface, the teeth comprising peaks having a peak-to-peak distance of from about 0.5 millimeters to about 2.5 millimeters, wherein the teeth have an amplitude above a centerline of from about 0.5 millimeters to about 2.5 millimeters.

12. A substrate retaining clamp for a substrate processing chamber, the retaining clamp comprising:
(a) a ring comprising an annular portion that surrounds a substrate in the chamber, and an overhang ledge that extends inwardly from the annular portion to cover a periphery of the substrate, wherein the ring comprises (i) a top surface that extends across the overhang ledge and annular portion, and (ii) an exterior side surface of the annular portion; and
(b) a knurled exposed surface on the top surface and exterior side surface, the knurled exposed surface comprising concentric and radially spaced apart knurled ridges and furrows, wherein the knurled ridges and furrows have an amplitude from a centerline that is at least about 0.5 millimeters and less than about 2.5 millimeters, and wherein adjacent knurled ridges have a peak-to-peak distance of at least about 0.5 millimeters and less than about 2.5 millimeters.

13. A clamp according to claim 12 wherein the exterior side surface is substantially perpendicular to the top surface.

14. A clamp according to claim 12 wherein the annular portion comprises first and second downwardly extending annular walls.

15. A clamp according to claim 12 wherein the first wall is adjacent to the periphery of the substrate, and the second wall is concentrically exterior to the first wall.
